(19) United States
(12) Patent Application Publication
(10) Pub. No.: US 2005/0135135 A1
(43) Pub. Date: Jun. 23, 2005

(54) Content addressable memory for CIDR address searches

(75) Inventors: Abhishek Sharma, Haryana (IN); Danish Hasan Syed, New Delhi (IN)

Correspondence Address: SEED INTELLECTUAL PROPERTY LAW GROUP PLLC, 701 FIFTH AVENUE, SUITE 6300, SEATTLE, WA, 98104-7092, US

(73) Assignee: STMicroelectronics Pvt. Ltd., Uttar Pradesh (IN)

(21) Appl. No.: 10/972,297

(22) Filed: Oct. 22, 2004

(30) Foreign Application Priority Data
Oct. 24, 2003 (IN) 1319/DEL/2003

(51) Int. Cl. G11C 15/00

(52) U.S. Cl. 365/49

(57) ABSTRACT

A Content Addressable Memory (CAM) with an improved the priority encoder enabling random storage of CIDR IP addresses in memory, including a plurality of data storage elements each having a first compare circuit for comparing a search key with the content of the data storage elements, the data storage elements storing data and associated prefix lengths; a match line associated with each first compare circuit to receive a signal representing a match or a mismatch of the compare data; and a priority encoder that receives match line signals and prefix lengths from data storage elements and provides a memory location address that corresponds to the matched longest prefix.

### BACKGROUND OF THE INVENTION

1. Field of the Invention

The present invention relates to a Content Addressable Memory (CAM) and, more particularly, to a CAM with an improved priority encoder for a Classless Inter Domain Routing (CIDR) address search.

2. Description of the Related Art

Content addressable memories are the memories that enable the comparison of a search data with internally stored data to provide addresses of the location where that search data is located in the memory. A CAM basically comprises of an array of data latches, a plurality of inputs for supplying search data and storing data in the CAM, and a plurality of output lines connected to a Priority Encoder (PE). The PE selects one of the multiple match line hits and provides an output corresponding to a first hit occurring closest to a zeroth location in the memory array.

A conventional PE can be used for applications such as CIDR, but with some constrains like storing of entries in a particular order. This constraint causes additional time-consuming tasks to be performed by the user. This overhead is known as Table Maintenance. Table Maintenance is a burden on a user, consuming valuable time and resources of an application.

The Internet Protocol (IP) addressing scheme governs transmission of data over the Internet. IPv4 is one of the commonly used IP addressing schemes. In this scheme a 32 bit long binary number represents an address. The 32-bit address is divided into four segments of equal size (8 bits). Each segment is identified by a dot separator and may independently assume any binary value ranging from 0 to 255, i.e., an IP address can be any address between 0.0.0.0 to 255.255.255.255. The addresses are further classified into three categories namely: Class A, Class B, Class C. In the Class-A addressing scheme the first 8-bit segment defines the Network ID while the remaining 24-bits define the Host ID. In the Class-B scheme, the first 2 segments (16-bits) define the Network ID and remaining 2 segments (16-bits) define the Host ID, while in the Class-C scheme the first 3 segments (24-bits) define the Network-ID and the last segment (8-bit) defines the Host-ID. Thus Class A, B and C schemes can accommodate networks having 256×256×256 (16,777,216), 256×256(65,536) and 255 terminals respectively.

This addressing scheme results in a large number of wasted addresses because Internet addresses are assigned in multiples of 255 as discussed above. For example, for a network of 100 terminals a class C scheme will assign the smallest number of addresses, namely 256, out of which only 100 will be used, resulting in wastage of 156 addresses. Similarly, for a Network of 300 terminals a Class B scheme will assign 65536 addresses that results in wastage of 65236 addresses. Such wastage of addresses is no longer affordable because of the rapid growth in the size of the global Internet's routing table.

A classless Inter Domain Routing (CIDR) scheme was developed to overcome this problem, by accurately allocating only the required size of address space. This scheme is explained by the following example.

A subnet of 192.60.128.0 includes all the addresses from 192.60.128.0 to 192.60.131.255. In this representation, the network portion of the address is 22 bits long, and the host portion is 10 bits long. The IP address in such a system is the f represented by adding the total number of bits that are to be masked after a slash e.g., the IP address 192.60.128.0, Subnet Mask 255.255.252.0 and the network address would be written simply as: 192.60.128.0/22.

The following examples further clarify the notation used:
192.60.128.0 (11000000.00111100.10000000.00000000).
Class C subnet address
192.60.129.0 (11000000.00111100.10000001.00000000)
Class C subnet address
192.60.130.0 (11000000.00111100.10000010.00000000)
Class C subnet address
192.60.131.0 (11000000.00111100.10000011.00000000)
Class C subnet address
192.60.128.0 (11000000.00111100.10000000.00000000)
Supernetted Subnet address
255.255.252.0 (11111111.11111111.11111100.00000000)
Subnet Mask
192.60.131.255 (11000000.00111100.10000011.11111111)
Broadcast address

The CIDR scheme is no different than the classful scheme for the case when 8(Class A), 16(Class B), 24(Class C) bits are masked. The following table lists the total number of host addresses possible for different Block prefixes in the CIDR scheme.

| CIDR Block | | No. of Host |
|---|---|---|
| Prefix | No. Equivalent Class C | Addresses |
| /27 | ⅛ th of a Class C | 32 hosts |
| /26 | ¼ th of a Class C | 64 hosts |
| /25 | ½ th of a Class C | 128 hosts |
| /24 | 1 Class C | 256 hosts |
| /23 | 2 Class C | 512 hosts |
| /22 | 4 Class C | 1024 hosts |
| /21 | 8 Class C | 2048 hosts |
| /20 | 16 Class C | 4096 hosts |
| /19 | 32 Class C | 8192 hosts |
| /18 | 64 Class C | 16,384 hosts |
| /17 | 128 Class C | 32,768 hosts |
| /16 | 256 Class C | 65,536 hosts |
| /15 | 512 Class C | 131,072 hosts |
| /14 | 1,024 Class C | 262,144 hosts |
| /13 | 2,048 Class C | 524,288 hosts |

Many present day implementations of the CIDR scheme arrange the IP addresses in a Content Addressable Memory (CAM) such that all the IP addresses with the longest prefix are stored in the location closest to the zeroth location of the CAM. This technique is often referred to as table management, and it is used because the priority decoder of the CAM provides an output corresponding to the first encountered match result while checking from zeroth memory location. These systems require the user to ensure that the CAM stores the IP address with highest prefix length at the lowest address of the CAM.

To ensure this, the CAM is divided into blocks of different sizes such that a block at the lowest address of the CAM is allocated for the IP addresses with the longest prefix and subsequent blocks for second longest prefix and so on as shown in FIG. 1. In other words, CIDR requires IP addresses to be arranged in blocks according to the prefix length. This requirement places a significant burden on the allocation process. For instance, if an IP address is to be located in a block that does not have an empty cell, then an empty cell has to be created by increasing the size of the block, which results in resizing of all the consecutive blocks until a block with an empty cell is found. Once an empty cell is found, in order to create an empty cell in the desired block, the top most element of the block with the empty cell has to be shifted to the empty cell, creating an empty cell at the top. Subsequent blocks then have to be resized to include the new empty cell, with the process being repeated until an empty cell is created in the desired block to store IP address, as shown in FIG. 2. This exercise is both cumbersome and time consuming and can sometimes result in resizing of the entire CAM.

In U.S. Pat. No 6,237,061 a method for finding the longest prefix match is described. This method requires Table Management as discussed above.

Further U.S. Pat. No. 6,460,112 describes a method and device for CIDR without requiring table management and allowing the CAM to be arbitrarily loaded with CIDR addresses into the CAM device. This patent requires two internal searches to be conducted, a location that is found in these two searches is the location with longest prefix match. The first search is on a data word to find the longest prefix among the hit locations, and the second is on a mask (prefix) word to find entries with that longest mask. Only one location will succeed in both searches and will drive a ROM (Priority Encoder) word-line. In this patent, prefix logic circuits determine the longest prefix among the CAM locations that matches the search key, regardless of where the matching locations are located in the CAM array. Once the prefix is known it then searches which location has that prefix through prefix match-lines. This patent has additional hardware than a conventional CAM array, as both data and mask bit have compare logic. Thus both have comparand bit-lines, match-lines, and data lines. It also has a prefix-logic (2-input NAND gate) for data and mask bit. Also, operation cannot be pipelined until both searches are completed for maximum throughput. Thus, time for searching a next CIDR address would require time taken for both searches.

### BRIEF SUMMARY OF THE INVENTION

The disclosed embodiments of the present invention are directed to an improved priority encoder with the CAM removing the requirement for the table management resulting in a more efficient implementation.

In accordance with one embodiment of the invention, a circuit is provided that includes a memory array having randomly stored data; a counter configured to generate counter values; a comparator circuit coupled to the memory array and the counter and configured to compare selected data from the memory array and to generate an enabling signal on a line corresponding to each selected data having a value that matches the counter value; and a register coupled to the comparator circuit and configured to store an index value associated with a memory device that corresponds to a selected data having a greatest value.

In accordance with another embodiment of the invention, a priority encoder is provided for use with a memory array, the encoder including a plurality of comparator circuits, each comparator circuit having a first input to receive an enable signal from the memory array and a second input to receive a prefix signal from the memory array, and an output; a counter circuit coupled to the plurality of comparator circuits and configured to generate a counter value, each comparator circuit configured to compare the counter value to a respective prefix signal and to generate an activation signal on the output thereof when the counter value matches the respective prefix signal; and a storage circuit coupled to the outputs of the plurality of comparators and configured to store an index value associated with a prefix signal having a greatest value.

In accordance with a method of the present invention, a sorting of data is provided, the method including receiving data selected from a first memory; and comparing incremented counter values to values associated with the selected data and determining the selected data with the highest value, and storing in a second memory an address value associated with the selected data determined to have the highest value.

In accordance with another embodiment of the invention, a sorting method is provided that includes receiving in a comparator block selected data regarding information stored in a memory array; generating a counter value; comparing the counter value to the selected data and generating an actuation signal in response thereto; storing a memory value associated with the actuation signal and replacing any previously stored memory value; and repeating the generating and comparing until a maximum counter value is reached whereby selected data representing a greatest value from among the selected data received in the comparator block is stored.

In accordance with still yet another method of the present invention, a method of sorting IP address values is provided that includes receiving at least one prefix associated with the IP address stored in the memory array; comparing the prefix to a counter value and generating a signal when the counter value matches the prefix value; storing in a second memory an index value associated with the prefix in response to the signal, including replacing any previously stored memory value; and repeating the comparing and storing until a maximum counter value is reached whereby the stored memory value represents a greatest prefix value from among the prefix values received in the comparator block.

In accordance with a further embodiment of the invention, a Content Addressable Memory (CAM) with an improved priority encoder enabling random configuration of memory is provided that includes a plurality data storage elements each having a first compare circuit for comparing search key with the content of the data storage elements, the data storage elements storing data and associated prefix lengths; a match line associated with each first compare circuit to receive a signal representing match or mismatch of the compare data; and a priority encoder that receives match line signals and prefix lengths from data storage elements and provides a memory location address that corresponds to a matched longest prefix.

The priority encoder includes a logic block connected to a memory array that stores addresses of CAM locations and registering elements that register the output of the memory array.

The logic block includes a plurality of compare blocks, each compare block receiving a match line to enable the compare operation and prefix length, each compare block connected to a global n bit counter, n being the total number of bits in the longest possible prefix, to compare the counter values with the prefix length, and to enable the output line of the logic block corresponding to a match. Ideally, the global counter counts from 0 to a maximum possible number in n bits.

In accordance with another aspect of the invention, the registering element registers each output of the memory array and retains only the latest registered value, and the compare block is formed of logic gates.

In accordance with a further aspect of the invention, the memory array is further connected to a registering block that registers memory location address of longest prefix match. Preferably, the registering block includes a selection circuit receiving its first input from the memory array connected to a registering element providing its output as the output of the priority encoder, which is the second input to the multiplexer. The selection circuit receives a selection signal from the outputs of the compare blocks for enabling registering operation and the selection means is a multiplexer.

In accordance with yet another aspect of the invention, a method for determining the address of the location of the contents having a longest prefix length that matches the search key in a content addressable memory containing data and associated memory is provided. The method includes comparing data stored in a plurality data storage elements with a search key; generating a match signal for each match in the compare; receiving match signals and prefix lengths in priority encoder; determining longest prefix amongst matched signals in priority decoder; and providing memory location address corresponding to the longest prefix.

The longest prefix is determined by generating a number corresponding to prefix length; comparing the number with each prefix length; selecting output lines corresponding to the matched prefix length; registering memory location address corresponding to the matched prefix length in a register; and repeating the above steps after incrementing/decrementing the number until the number is less/greater then the highest/lowest prefix length.

### BRIEF DESCRIPTION OF THE ACCOMPANYING DRAWINGS

The disclosed embodiments of the present invention are described in conjunction with the accompanying drawings, wherein:

FIG. 1 is a block diagram of a CAM;

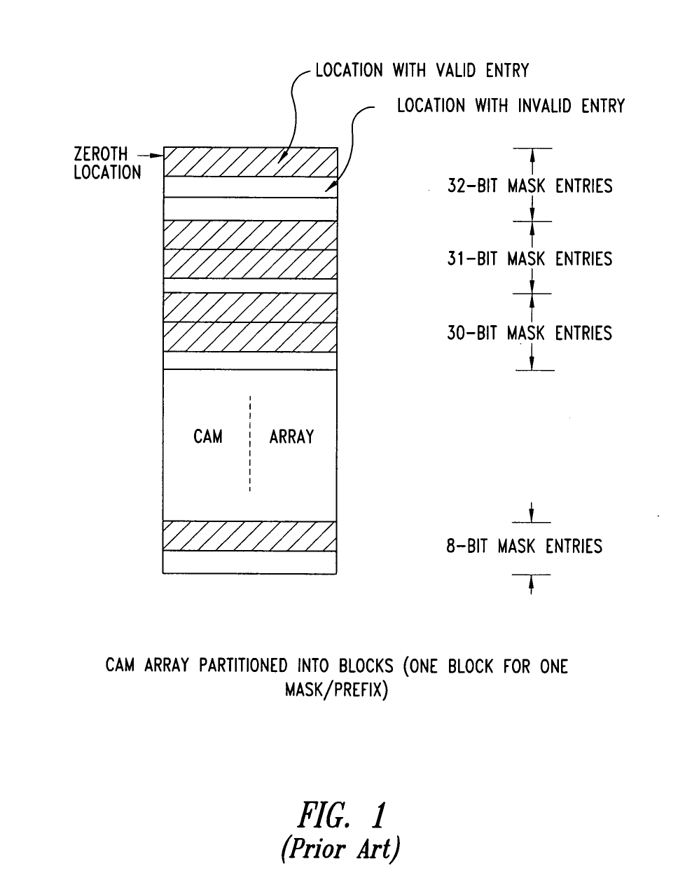

FIG. 2 shows the shift operation in the CAM for creating an empty cell in a block;

FIG. 3 shows the CAM with comparison circuitry in accordance with the present invention;

FIG. 4 shows an example of the longest prefix match search in a CAM according to the present invention; and

FIG. 5 shows a detailed diagram of the comparator.

### DETAILED DESCRIPTION OF THE INVENTION

The disclosed embodiment of the present invention provides an improved priority encoder with additional hardware for comparison in the CAM, removing the requirement for the table management and thus resulting in a time efficient device. The CAM includes a memory array having data storage locations and a first compare circuit for comparing a search key with the stored data, such as the prefix of an IP address, and generating signal on a match line representing a match or hit or representing a mismatch.

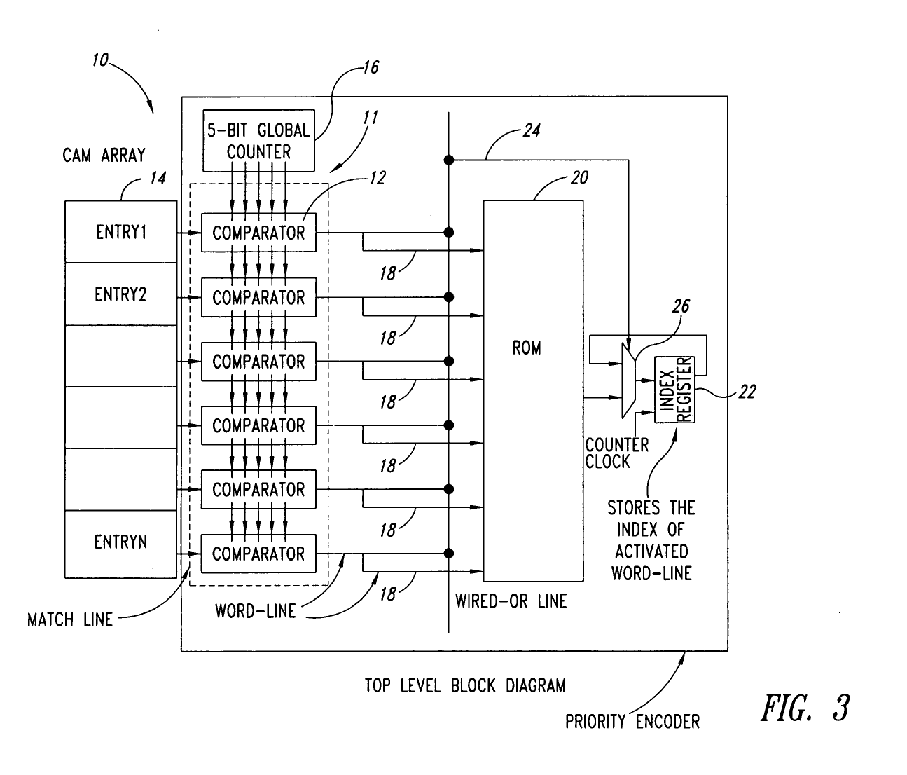

Referring to FIG. 3, a CAM 10 with an improved priority encoder 11 having comparison circuitry in accordance with the present invention is illustrated. A Comparator block 12 receives a hit signal and the corresponding prefix from each location of a CAM array 14. Each Comparator Block 12 further receives input from a Counter 16. The Counter 16 is a five-bit counter set to count from 0 to 31. Each Comparator Block 12 compares the counter's value with the prefix length associated with each location and enables a respective word-line 18 of a Random Access Memory (ROM) 20 depending on whether there is a hit at that location or not. The ROM 20 outputs the index of the activated word-line that is registered in an Index register 22. The ROM word-lines 18 are also “wired OR” for selecting an input to the Index Register 22. This wired-OR line 24 is the select line of a MUX 26. It is active at the instances when a hit location's prefix matches with the contents of counter 16.

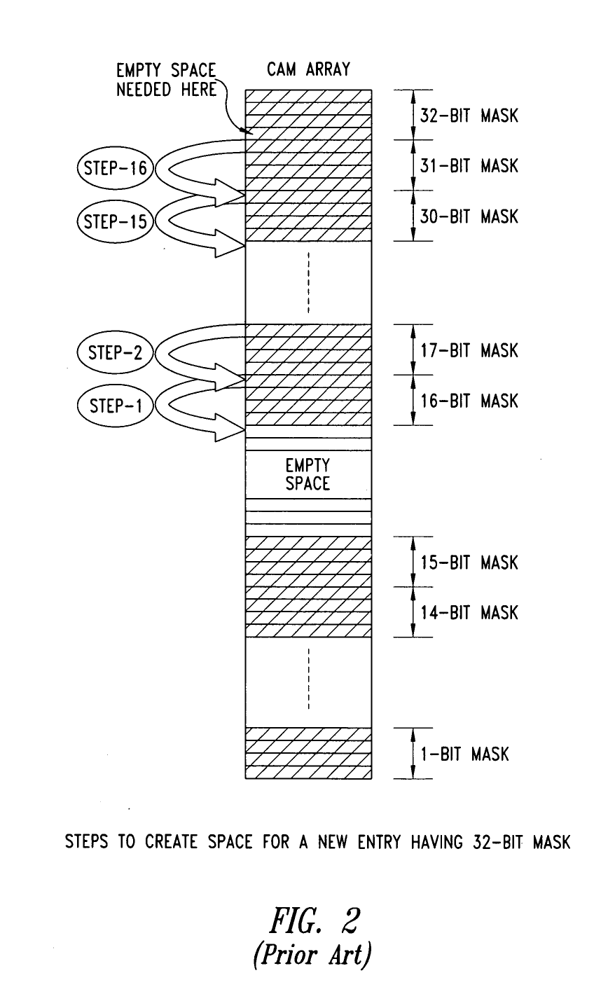

For each hit, the index register 22 registers the location of hit entries through the multiplexer 26 which takes inputs from the ROM 20 or previous self-contents through a feedback path. The Counter 16 counts (prefix) from 0 to 31 and at the end of the count, the Index register 22 has the location of the entry having the longest prefix. This is passed to the user as an Index to a memory storing information corresponding to the Longest Prefix Matching entry. This scheme obviates the need of storing CIDR IP entries in a predetermined locations, thus reducing the requirement for table management, which is necessary in previous scenarios as explained with respect to FIG. 2. An illustrative example describes the invention as follows.

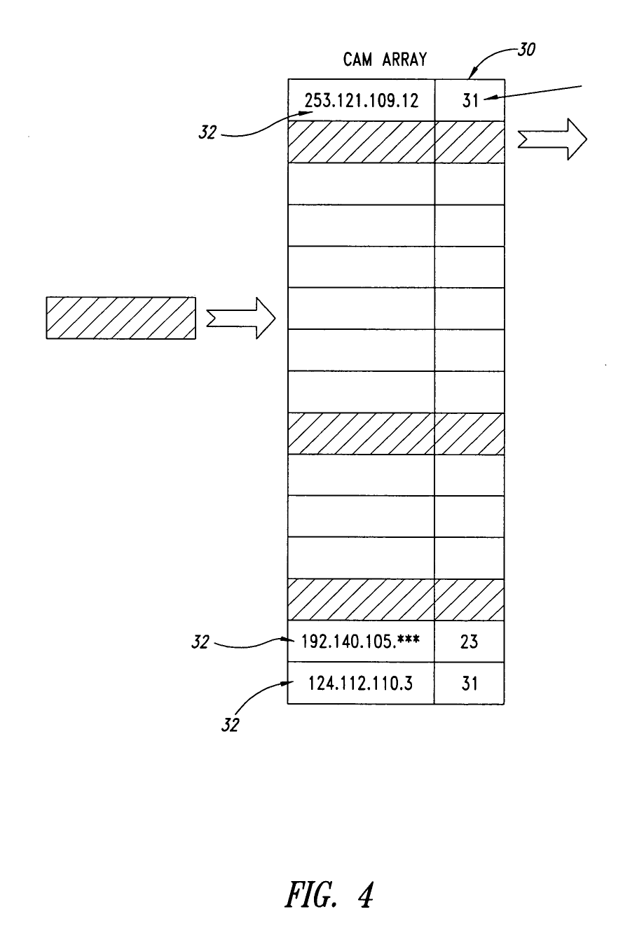

FIG. 4 describes the longest prefix match algorithm. It shows a CAM 30 with randomly stored IP addresses 32 (i.e., not stored according to their prefixes). Prefixes need 5-bit storage, so a value of 0-31 is for a prefix range of 1-32. A search of IP address 209.131.105.42 will produce three hits namely: 209.***.***.*** with prefix 7; 209.131.105.42 with prefix 31; and 209.131.***.*** with prefix 15. The counter then starts counting from 0 to 31. The comparator then compares the length of the prefixes with the counter's value and activates the corresponding ROM word-line. The ROM provides the indexes (location of the entries) of these word-lines, which are registered in the Index register with the help of a MUX. The select line of the MUX decides the instants when the output of the ROM needs to be registered. Since the counter is counting from 0 to 31, each hit entry's location is overwritten by the next longer prefix matching entry's location. Thus, after the counter completes the count of 31, the index register has the location of longest prefix matching entry. In this example the result at the output is 7 (location of the longest prefix matching entry), since 209.131.105.42 entry has a prefix of 31 (highest among the matching entries).

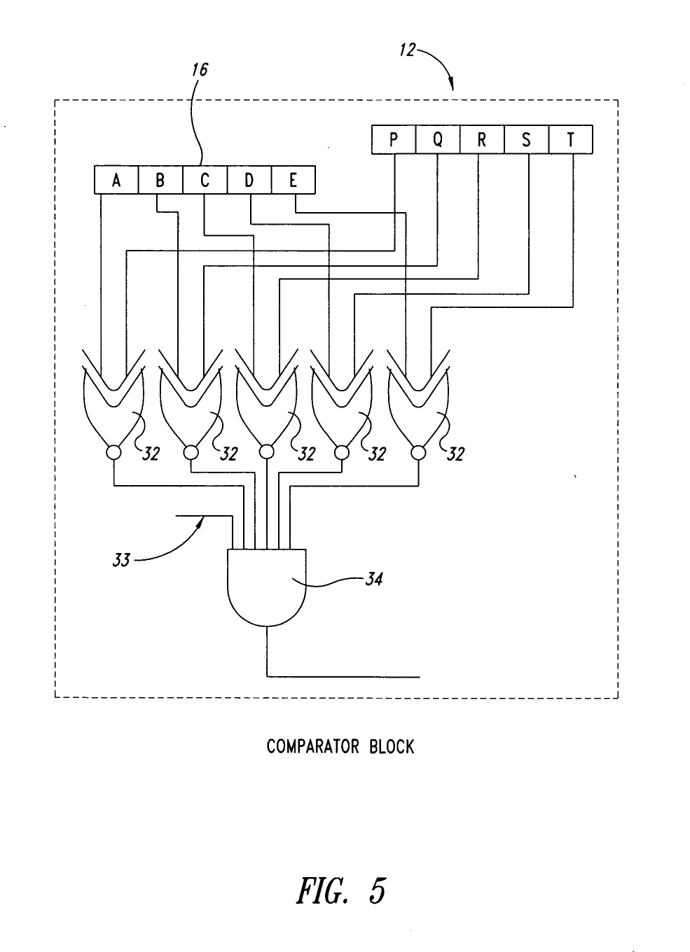

FIG. 5 shows a detailed diagram of the comparator block 12 associated with each hit line. The blocks A-E are the output of the counter 16, and P-T are the prefix contents. The comparator 12 includes logic gates 32, each logic gate 32 compares a bit of the counter 16 with the prefix content and provides a high or low signal to an AND gate 34. The counter 16 is a global counter. After a search the counter 16 will be reset and start comparing prefixes of all locations to find the longest prefix. The AND gate 34 has the Match line 33 as enabling/disabling signal. The match line will remain high if a hit signal has occurred. Suppose multiple hits have occurred for prefixes 8, 16 and 32, then starting from 00000, the counter will start counting and will return the longest prefix match to the ROM, which is 11111 (32) in this particular case.

Thus the invention provides a method and device for a finding a longest prefix matching without requiring any table management and hence providing an efficient solution.

All of the above U.S. patents, U.S. patent application publications, U.S. patent applications, foreign patents, foreign patent applications and non-patent publications referred to in this specification and/or listed in the Application Data Sheet, are incorporated herein by reference, in their entirety.

From the foregoing it will be appreciated that, although specific embodiments of the invention have been described herein for purposes of illustration, various modifications may be made without deviating from the spirit and scope of the invention. Accordingly, the invention is not limited except as by the appended claims.

1. A Content Addressable Memory (CAM) with an improved priority encoder enabling random configuration of memory, comprising:
a plurality of data storage elements, each data storage element having a first compare circuit for comparing a search key with the content of the data storage elements, the data storage elements storing data and associated prefix lengths;
a match line associated with each first compare circuit to receive a signal representing a match or a mismatch of the compare data; and
a priority encoder that receives match line signals and prefix lengths from the data storage elements and provides a memory location address that corresponds to matched a longest prefix.

2. The CAM of claim 1 wherein the priority encoder includes a logic block connected to a memory array that stores addresses of CAM locations and registering elements that register the output of the memory array.

3. The CAM of claim 2 wherein the logic block includes a plurality of compare blocks, each compare block receiving a match line to enable the compare operation and prefix length, each compare block connected to a global n bit counter, n being the total number of bits in the longest possible prefix, to compare the counter values with the prefix length and to enable the output line of the logic block corresponding to a match.

4. The CAM of claim 2 wherein the global counter counts from 0 to a maximum possible number of n bits.

5. The CAM of claim 2 wherein the registering element registers each output of the memory array and retains only the latest registered value.

6. The CAM of claim 3 wherein the compare block comprises logic gates.

7. The CAM of claim 1 wherein the output of the memory array is further connected to a registering block that registers memory location address of the longest prefix match.

8. The CAM of claim 5 wherein the registering block includes a selection means receiving its first input from the memory array and connected to a registering element providing its output as the output of the priority encoder and as a second input to the multiplexer.

9. The CAM of claim 8 wherein the selection means receives a selection signal from the outputs of the compare blocks for enabling a registering operation.

10. The CAM of claim 8 wherein the selection means is a multiplexer.

11. A method for determining the address of the location of the contents having the longest prefix length that matches a search key in a content addressable memory containing data and associated memory, comprising the steps of:
comparing data stored in a plurality of data storage elements with a search key;
generating a match signal for each match in the compare;
receiving match signals and prefix lengths in a priority encoder;
determining longest prefix amongst matched signals in the priority decoder; and
providing a memory location address corresponding to the longest prefix length.

12. The method of claim 11 wherein said longest prefix is by:
generating a number corresponding to a prefix length;
comparing the number with each prefix length;
selecting output lines corresponding to a matched prefix length;
registering a memory location address corresponding to the matched prefix length in a register; and
repeating the above steps after incrementing/decrementing the number until the number is less than the lowest prefix length or greater than the highest prefix length.

13. A sorting method, comprising:
receiving data selected from a first memory; and
comparing incremented counter values to values associated with the selected data and determining the selected data with the highest value, and storing in a second memory a value associated with the selected data determined to have the highest value.

14. The method of claim 13 wherein the selected data comprises an IP address prefix.

15. The method of claim 14 wherein the value of the second memory comprises an index value associated with a location address in the second memory that corresponds to a longest IP prefix.

16. The method of claim 13 wherein comparing incremented counter values comprises activating a word-line as input to a ROM for each counter value that matches a value associated with the selected data.

17. A sorting method, comprising:
receiving in a comparator block selected data regarding information stored in a memory array;
generating a counter value;
comparing the counter value to the selected data and generating an actuation signal in response thereto;
storing a memory value associated with the actuation signal and replacing any previously stored memory value; and
repeating the generating and comparing until a maximum counter value is reached whereby selected data representing a greatest value from among the selected data received in the comparator block is stored.

18. The method of claim 17 wherein repeating the generating and comparing comprises incrementing a counter to generate a new counter value.

19. The method of claim 17 wherein storing a memory value comprises storing in a register an index value that corresponds to a location address in a memory associated with the data representing the greatest value.

20. A method of retrieving IP address values stored in a memory array, comprising:
receiving at least one prefix associated with the IP address stored in the memory array;
comparing the prefix to a counter value and generating a signal when the counter value matches the prefix value;
storing in a second memory an index value associated with the prefix in response to the signal, including replacing any previously stored memory value; and
repeating the comparing and storing until a maximum counter value is reached whereby the stored memory value represents a greatest prefix value from among the prefix values received in the comparator block.

21. The method of claim 20 wherein generating a signal comprises activating a word-line as an input to a ROM.

22. The method of claim 20 wherein the memory value comprises an index value associated with a location address in the ROM.

23. A circuit, comprising:
a memory array having randomly stored data;
a counter configured to generate counter values;
a comparator circuit coupled to the memory array and the counter and configured to compare selected data from the memory array and to generate an enabling signal on a line corresponding to each selected data having a value that matches the counter value; and
a register coupled to the comparator circuit and configured to store an index value associated with a memory device that corresponds to selected data having a greatest value.

24. The circuit of claim 23 wherein the data stored in the memory array comprises at least IP address prefixes.

25. A priority encoder for use with a memory array, comprising:
a plurality of comparator circuits, each comparator circuit having a first input to receive an enable signal from the memory array and a second input to receive a prefix signal from the memory array, and an output;
a counter circuit coupled to the plurality of comparator circuits and configured to generate a counter value, each comparator circuit configured to compare the counter value to a respective prefix signal and to generate an activation signal on the output thereof when the counter value matches the respective prefix signal; and
a storage circuit coupled to the outputs of the plurality of comparators and configured to store index values associated with respective prefix signals to generate on an output index value associated with an IP prefix having a greatest value.

26. The priority encoder of claim 25 wherein the comparator circuits are activated upon receipt of the enable signal.

27. The encoder of claim 25 wherein the index value corresponds to an address location in a ROM associated with the greatest prefix value.
